(19) United States
(12) Patent Application Publication
(10) Pub. No.: US 2014/0264726 A1
(43) Pub. Date: Sep. 18, 2014

(54) STRUCTURE AND METHOD FOR PROTECTED PERIPHERY SEMICONDUCTOR DEVICE

(71) Applicant: Macronix International Co., Ltd., Hsin-chu (TW)

(72) Inventors: Yao-Fu Chan, Changhua County (TW); Ta-Kang Chu, Hsinchu City (TW); Pi-Shan Tseng, Tainan City (TW)

(21) Appl. No.: 13/920,565

(22) Filed: Jun. 18, 2013

Related U.S. Application Data
(60) Provisional application No. 61/778,482, filed on Mar. 13, 2013.

(51) Int. Cl. H01L 29/06; H01L 21/762

(52) U.S. Cl. CPC H01L 29/0649; H01L 21/76224
USPC 257/510; 438/424

(57) ABSTRACT

A semiconductor device is provided having reduced corner thinning in a shallow trench isolation (STI) structure of the periphery region. The semiconductor device may be substantially free of any corner thinning at a corner of a STI structure of the periphery region. Methods of manufacturing such a semiconductor device are also provided.

### CROSS-REFERENCE TO RELATED APPLICATIONS

This application claims priority to U.S. Provisional Application Ser. No. 61/778,482 filed Mar. 13, 2013, the contents of which is fully incorporated herein by reference.

### TECHNOLOGICAL FIELD

The present invention generally relates to a structure of a semiconductor device and a method of forming the semiconductor device. In particular, the present invention relates to methods of manufacturing shallow trench isolation (STI) structures and semiconductor devices having such improved STI structures.

### BACKGROUND

Conventionally, a shallow trench isolation (STI) structure includes the steps of forming an oxide layer and a patterned mask layer on a substrate. A portion of the substrate, as defined by the patterned mask, is removed to form a shallow trench. The shallow trench is then filled using a dielectric material. Next the oxide layer and the patterned mask layer are removed typically by etching.

During the step of removing the oxide layer and the patterned mask layer, a portion of the defined STI structure may also be removed. In particular, the upper corner of the STI structure is particularly susceptible to removal during this removal step sometimes resulting in the formation of a divot at the upper corner. A subsequently applied tunnel oxide layer or a gate oxide layer will then be non-uniform especially in the upper corner region of the STI structure, a phenomena that is referred to herein as “corner thinning.” The formation of a divot and corner thinning of an STI structure may affect the characteristics and perhaps the reliability of the semiconductor device.

While certain techniques have been adopted to reduce the extent of corner thinning, the amount of material etched or removed in an open region such as the periphery region of a semiconductor device tends to be greater than the amount of material etched or removed in a dense region such as the array region of the memory device. Therefore, the techniques known in the art for reducing the formation of divots and corner thinning of STI regions in the array region have not been effective in reducing corner thinning of STI structures in the periphery region. There remains a need in the art for improved methods of manufacturing semiconductor devices with STI structures in the periphery region having little to substantially no corner thinning. Furthermore, there remains a need in the art for semiconductor devices having STI structures in the periphery region having little to substantially no corner thinning.

### BRIEF SUMMARY OF EXEMPLARY EMBODIMENTS

Embodiments of structures, methods, and devices of the present invention are therefore provided that may provide for a semiconductor device having reduced corner thinning in STI structures in the periphery region.

An aspect of the invention provides semiconductor devices comprising a first shallow trench isolation (STI) structure that is formed in an open region such as, for example, a periphery region of the semiconductor device; a first stack structure, a portion of the first STI structure defined by the first stack structure; a trench-end offset having a distance measured from a corner of the first STI structure to an edge of the first stack of the open region; a second STI structure formed in a dense region such as, for example, an array region of the semiconductor device; and a second stack structure in the dense region, a portion of the second STI structure defined by the second stack structure. According to certain embodiments of the invention, a sidewall of the second STI structure is substantially coextensive with an edge of the second gate stack in the dense region.

In some embodiment of the inventions, the distance of the trench-end offset is up to about 200 Å.

In some embodiments of the invention, a semiconductor device may comprise a dielectric layer applied to the semiconductor device that is substantially free of corner thinning at the corner of the first STI structure. In certain embodiments of the invention, the dielectric layer is a gate oxide layer. In certain embodiments of the invention, a second conductive layer is applied to the dielectric layer.

An embodiment of the invention may also provide a semiconductor device comprising an interface region for a first region such as, for example, a periphery region and a second region such as, for example, an array region on a substrate; a stack structure in the interface region, the stack structure having a first edge adjacent to the first region and a second edge adjacent to the second region; a first shallow trench isolation (STI) structure distal-proximate to the first edge of the stack structure; a trench-end offset having a distance measured from a top corner of the first STI structure to the first edge of the stack structure in the first region; and a second STI structure distal-proximate to the second edge of the stack structure. According to an embodiment of the invention, a sidewall of the second STI structure is substantially coextensive with the second edge of the stack structure.

An aspect of the invention also provides a method of fabricating a semiconductor device. Certain embodiments of methods of the invention for fabricating a semiconductor device comprise the steps of providing a semiconductor device having a substrate, a first dielectric layer, a first conductive layer, and a second dielectric layer; patterning and etching the semiconductor device to form one or more trenches defining one or more shallow trench isolation (STI) structures in a dense region such as, for example, an array region and at least one STI structure in an open region such as, for example, a periphery region; applying a first photoresist layer to the dense region; depositing a third dielectric layer or a liner layer on the semiconductor device; and etching to achieve a desired depth of the at least one STI structure and leaving a protective portion of the third dielectric layer or liner layer at a sidewall of the at least one STI structure. The method of fabricating a semiconductor device may additionally comprise removing the third dielectric layer or liner layer while leaving behind a trench-end offset area. In certain embodiments of the invention, the second dielectric layer may comprise more than one dielectric layer such as a dual hard mask layer.

In some embodiments of the invention, a method of manufacturing a semiconductor device may additionally comprise the steps of removing the third dielectric layer or liner layer to define an open space in the sidewall of the at least one STI structure, removing the first photoresist layer, applying a second photoresist layer to the open region, etching the one or more STI structures to another desired depth, and removing the second photoresist layer.

According to certain embodiments of the invention, the protective portion of the third dielectric layer or the liner layer may be at least about 200 Å. In certain embodiments of the invention, a stack defining the at least one STI structure has a trench-end offset. The trench-end offset may have a distance measured from a corner of the at least one STI structure to the first dielectric as the trench-end offset follows substantially along the surface of the substrate. More specifically, the distance may be measured from a corner of the at least one STI structure to an edge of a stack in the open region in part defining the at least one STI structure. In some embodiments of the invention, the distance of the trench-end offset may be at least about 200 Å.

According to certain embodiments of methods of the invention of manufacturing a semiconductor device of the invention, a stack defining any one of the one or more STI structures may be substantially free of any trench-end offset.

In certain embodiments of the invention, the method of fabricating a semiconductor device may comprise applying a fourth dielectric layer or a dielectric fill to substantially fill the one or more STI structures, the at least one STI structure, and the open space. In certain embodiments of the invention, the fourth dielectric layer or dielectric fill is substantially free of any divots.

In certain embodiments of the invention, the method of fabricating a semiconductor device may comprise applying a fifth dielectric layer to the semiconductor device. Pursuant to some embodiments of the invention, the fifth dielectric layer may be substantially free of corner thinning at an upper corner of the at least one STI structure.

In certain embodiments of the invention, a semiconductor device manufactured according to certain embodiments of the method for fabricating such a semiconductor device may have a stack defining the at least one STI structure having a trench-end offset that is defined by a distance measured from a corner of the at least one STI structure to the first dielectric layer following substantially along a surface of the substrate. Further pursuant to these certain embodiments, the distance may be up to about 200 Å. In yet other embodiments of the invention, a stack defining the one or more STI structures may be substantially free of any trench-end offset.

An aspect of the invention provides semiconductor devices fabricated according to processes or methods for fabricating a semiconductor device of the invention.

These embodiments of the invention and other aspects and embodiments of the invention will become apparent upon review of the following description taken in conjunction with the accompanying drawings. The invention, though, is pointed out with particularity by the appended claims.

### BRIEF DESCRIPTION OF THE SEVERAL VIEWS OF THE DRAWING(S)

Having thus described the invention in general terms, reference will now be made to the accompanying drawings, which are not necessarily drawn to scale, and wherein:

FIG. 1 is a cross-sectional view illustrating a basic stack film structure of a conventional semiconductor device;

FIG. 2 is a cross-sectional view illustrating a conventional method of fabricating shallow trench isolation structures;

FIGS. 3A to 3D are cross-sectional views illustrating another conventional method of fabricating shallow trench isolation structures;

FIG. 4 is a cross-sectional view illustrating a semiconductor device according to an embodiment of the invention;

FIGS. 5A-5F are cross-sectional views illustrating a method of fabricating shallow trench isolation structures according to an embodiment of the invention;

FIG. 6A is a cross-sectional view of a semiconductor device according to an embodiment of the invention;

FIG. 6B is a detailed view of the STI structure of an open region of FIG. 6A according to an embodiment of the invention;

FIG. 7A is a detailed cross-sectional view of a conventional STI structure in an open region having divots at the upper corner of the STI structure;

FIG. 7B is a detailed cross-sectional view of a conventional STI structure of an open region after a gate oxide layer has been applied to the open region of the semiconductor device;

FIG. 8A is a detailed cross-sectional view of a STI structure of an open region before the application of a another dielectric layer according to an embodiment of the invention;

FIG. 8B is a detailed cross-sectional view of a STI structure of an open region after the application of a another dielectric layer according to an embodiment of the invention;

FIG. 9A is a profile of an exemplary embodiment of a semiconductor device that has been partially processed according to a method of the invention;

FIG. 9B is a detailed profile view of a plurality of array STI structures of a semiconductor device fabricated according to a method of the invention;

FIG. 9C is a detailed profile view of a portion of a STI structure in an open region of a semiconductor device fabricated according to a method of the invention;

FIG. 10 is a schematic view of an upper corner of a STI structure in an open region of a conventional semiconductor device;

FIG. 11 is a schematic view of an upper corner of a STI structure in an open region according to an embodiment of the invention;

FIG. 12 is a block diagram showing processing modules for fabricating a semiconductor device according to an embodiment of the invention; and

FIG. 13 is a flowchart showing the steps of fabricating a semiconductor device according to another embodiment of the invention.

### DETAILED DESCRIPTION

Some embodiments of the present invention will now be described more fully hereinafter with reference to the accompanying drawings, in which some, but not all embodiments of the invention are shown. Indeed, various embodiments of the invention may be embodied in many different forms and should not be construed as limited to the embodiments set forth herein; rather, these embodiments are provided so that this disclosure will satisfy applicable legal requirements.

As used in the specification and in the appended claims, the singular forms “a”, “an”, and “the” include plural referents unless the context clearly indicates otherwise. For example, reference to “a STI structure” includes a plurality of such STI structures.

Although specific terms are employed herein, they are used in a generic and descriptive sense only and not for purposes of limitation. All terms, including technical and scientific terms, as used herein, have the same meaning as commonly understood by one of ordinary skill in the art to which this invention belongs unless a term has been otherwise defined. It will be further understood that terms, such as those defined in commonly used dictionaries, should be interpreted as having a meaning as commonly understood by a person having ordinary skill in the art to which this invention belongs. It will be further understood that terms, such as those defined in commonly used dictionaries, should be interpreted as having a meaning that is consistent with their meaning in the context of the relevant art and the present disclosure. Such commonly used terms will not be interpreted in an idealized or overly formal sense unless the disclosure herein expressly so defines otherwise.

As used herein, “shallow trench” is intended to mean the structure employed in shallow trench isolation (“STI”) of a semiconductor device. Generally, a shallow trench is defined by sidewalls and a bottom. However, in some shallow trenches, depending on the aspect ratio and depth of the trench, the formation of a distinct bottom portion, in some cases, may not be clearly distinguishable from the convergence of the sidewalls at the bottom portion of the trench.

The inventors have conceived of a semiconductor device having reduced corner thinning for gate oxide in a STI in an open region such as, for example, a periphery region of the semiconductor device. In certain embodiments of the invention, methods provide an improved semiconductor device of the invention while having a substantial reduction in the extent of corner thinning in a STI of the open region.

FIGS. 1 and 2 are cross-sectional views illustrating a conventional method of fabricating shallow trench isolation structures. As shown in FIG. 1A, a semiconductor device 10 is provided having a dense region 20 such as, for example, an array region and an open region 30 such as, for example, a periphery region defined by an interface region 40 or boundary region. The semiconductor device has a substrate 50, the substrate 50 continuously extending from the dense region 20 and the open region 30. A well implant 60 is disposed in the substrate 50 in the dense region 20, and another well implant 70 is disposed in the substrate 50 in the open region 30.

A tunnel oxide layer 80 is formed across the substrate 50 at the dense region 20 and a gate oxide layer 90 is formed across the substrate 50 at the open region 30. A conductive layer such as, for example, a polysilicon layer 100 is disposed across the tunnel oxide layer 80 and the gate oxide layer 90. A silicon nitride layer 110 is disposed across the polysilicon layer 100. An oxide layer 120 is disposed along the silicon nitride layer 110.

As further illustrated in FIG. 2, conventionally, a patterned mask layer 130 is applied along the oxide layer 120. One or more STI structures 140 are etched in the semiconductor device 10 in the dense region. At least one STI structure 150 is etched in the semiconductor device 10 in the open region 30.

FIGS. 3A to 3D are cross-sectional views illustrating another conventional method of fabricating shallow trench isolation structures. FIG. 3A shows a cross-section of the semiconductor device 10 after a patterned mask layer has been applied and the semiconductor device 10 has been etched to form one or more STI structures 160 in the dense region 20 and at least one STI structure 170 in the open region 30.

As shown in FIG. 3B, an open region photoresist layer 180 is applied to the oxide layer 120 of the open region 30 filling the at least one STI structure 170. The one or more STI structures 162 are further etched to a desired depth. The open region photoresist layer 180 is removed during and/or after the plurality of STI structures 162 are further etched to a desired depth.

As shown in FIG. 3C, a dense region photoresist layer 190 is applied to the oxide layer 120 of the dense region 20 and fills the one or more STI structures 162. FIG. 3D is a cross-sectional view of the conventional semiconductor device 10 after the at least one STI structure 172 has been further etched to a desired depth.

FIGS. 4 and 5A to 5B are cross-sectional views illustrating a method of fabricating shallow trench isolation structures according to an embodiment of the invention. As shown in FIG. 4, a semiconductor device 210, which is different than the semiconductor device 10 of FIG. 1, is provided having a dense region 220 such as, for example, an array region and an open region 230 such as, for example, a periphery region defined by an interface region 240. The semiconductor device has a substrate 250, the substrate 250, according to this illustrative embodiment of the invention, continuously extending from the dense region 220 and the open region 230. According to certain embodiments of the invention, the substrate 250 may be, for example, an n-type doped silicon substrate, a p-type doped silicon substrate, an epitaxial silicon substrate, a gallium arsenide substrate, a germanium silicide substrate, an indium phosphide substrate, or any combination thereof. A well implant 260 is disposed in the substrate 250 of the dense region 220, and another well implant 270 is disposed in the substrate 250 of the open region 230.

A first dielectric layer 280, extending substantially along the substrate 250 at the dense region 220 and the open region 230, is formed across the substrate 250. In an embodiment of the invention, the first dielectric layer 280 may be a tunnel oxide layer. The first dielectric layer 280 may be formed using, for example, a thermal oxidation process or a chemical vapor deposition process.

A conductive layer 300 is disposed across the first dielectric layer 280. A second dielectric layer 310 & 320 may be disposed across the conductive layer 300. According to an embodiment of the invention, the conductive layer 300 may be a polysilicon layer. In the exemplary embodiment of the invention represented by FIG. 4, the second dielectric layer 310 & 320 is a dual layer, or a dual hard mask layer. In another embodiment of the invention, a lower dielectric layer 310 of the second dielectric layer 310 & 320 may comprise a silicon nitride.

An upper dielectric layer 320 of the second dielectric layer 310 & 320 is disposed along the lower dielectric layer 310 of the second dielectric layer 310 & 320. In an embodiment of the invention, the upper dielectric layer 320 of the second dielectric layer 310 & 320 may comprise a silicon oxide, a silicon nitride, or any combination thereof.

As shown in FIG. 5A, a patterned mask layer may be applied to the semiconductor device 210 and one or more STI structures 360 may be formed in the dense region 220, and at least one STI structure 370 may be formed in the open region 230. FIG. 5B shows a cross-sectional view of the semiconductor device 210 having a dense region photoresist 380 applied to the dense region 220 of the semiconductor device 210. As shown in FIG. 5C, a third dielectric layer or a liner layer 390 is applied to the semiconductor device 210 of FIG. 5B. In certain embodiments of the invention, the liner layer 390 may be conformally applied to the semiconductor device 210. According to the illustrative embodiment of FIG. 5C, the liner layer 390 covers the surfaces of the dense region photoresist 380 in the dense region 220 and the surface of the second dielectric layer 310 & 320 and the sidewalls of the at least one STI structure 370 in the open region 230.

In an embodiment of the invention, the liner layer 390 may be a low temperature oxide (LTO) layer, for example. The LTO layer may be processed at approximately room temperature, for example. The LTO process may comprise the steps of introducing a Si-source to the reaction chamber, absorbing the source on the substrate of the semiconductor device resulting in a Si-source layer may have a volumetric dimension of about 0.2 to about 1 standard liter per minute (“slm”) or about 0.5 slm, according to certain embodiments of the invention. The exposure time may be about 6 seconds, for example.

A nitrogen purge step may then be used to purge any of the Si-source material from the chamber. Oxygen is then introduced into the chamber to form a volumetric dimension of about 5 to about 20 slm, or about 10 slm, according to certain embodiments of the invention. RF power is applied to produce an oxygen radical, and the oxygen radical may then react with the Si-source to form the oxide layer. In certain embodiments of the invention, the RF power is about 50 to about 100 W, and about 100 W, according to certain embodiments of the invention.

The chamber is then purged of un-reacted materials and the application steps as described may be repeated. One pass may produce a layer having a thickness of about 2 Å. The thickness will be determined by the number of passes the semiconductor device is subjected to.

The semiconductor device 210 of FIG. 5C may be subjected to etching to form a desired depth of the at least one STI structure 370. Following etching of the semiconductor device 210 of FIG. 5C, as shown in FIG. 5D, a portion of the liner layer 390 or the remaining liner layer 395 may be disposed about a portion of a sidewall 400 of the at least one STI structure 370. In certain embodiments of the invention, a thickness 410 of the remaining liner layer 395 at about the first dielectric layer 280 may be up to about 200 Å. In certain other embodiments of the invention, the thickness 410 of the remaining liner layer 395 at about the first dielectric layer 280 may be about 200 Å or more. In yet certain other embodiments of the invention, the thickness 410 of the remaining liner layer 395 at about the first dielectric layer 280 may be from about 200 Å to about 500 Å. According to still certain other embodiments of the invention, the thickness 410 of the remaining liner layer 395 at about the first dielectric layer 280 may be from about 500 Å to about 1000 Å. In an embodiment of the invention, the thickness 410 of the remaining liner layer 395 at about the first dielectric layer 280 is about 200 Å. Optionally, the semiconductor device 210 of FIG. 5D may be subjected to a cleaning process prior to undergoing additional processing steps.

FIG. 5E is a cross-section view of the semiconductor device 210 of the invention after the dense region photoresist 380 has been removed, an open region photoresist 420 has been applied to the open region 230 and filling the at least one STI structure 370, and the one or more STI structures 360 have been further etched to achieve a desired depth. As shown in the illustrative embodiment of FIG. 5E, the one or more STI structures 360 are etched in the substrate 250 of the dense region 220.

FIG. 5F is a cross-sectional view of the semiconductor device 210 after the open region photoresist 420 has been removed. Additionally, the second dielectric layer 310 & 320 has also been removed. Following this step, the one or more STI structures 360 and the at least one STI structure 370 are filled with a fourth dielectric layer or a dielectric fill 430. In certain embodiments of the invention, the dielectric fill 430 may comprise an oxide. Without intending to be limiting, the dielectric fill 430 may be formed in the one or more STI structures 360 and the at least one STI structure 370 using, for example, a chemical vapor deposition (CVD) process such as, for example, a plasma enhanced CVD (PECVD) process, an atmospheric pressure CVD (APCVD) process, a high-density plasma CVD (HDP-CVD) process, or a spin-on-dielectric (SOD) process. According to some embodiments of the invention, the dielectric fill 430 may be planarized by use of a chemical-mechanical polishing (CMP) process, for example.

As a result of the inventive method of fabricating the semiconductor device 210 of FIG. 5F, the semiconductor device 210 is substantially free of any divots. A fifth dielectric layer, such as a gate oxide layer, may be formed across the surface of the open region 230 of the semiconductor device 210 of FIG. 5F after the second dielectric layer 310 & 320 disposed along the open region 230 of the semiconductor device 210 has been removed. As a result of the semiconductor device 210 being substantially free of any divots, but without intending to be bound by theory, the fifth dielectric layer may be substantially free of corner thinning at the upper edge 440 of the at least one STI structure 370.

FIG. 6A is a cross-sectional view of a semiconductor device according to an embodiment of the invention. FIG. 6B is a detailed cross-sectional view of the at least one STI structure highlighted in portion B of FIG. 6A detailing the upper edge 440 of the at least one STI structure 370. Following processing to form a gate oxide layer, for example, FIG. 6 illustrates that there is a substantial reduction in corner thinning of the gate oxide layer.

FIG. 7A is a detailed cross-sectional view of a conventional STI structure in an open region such as, for example, a periphery region after the oxide layer has been removed, resulting in the formation of divots 194 at the upper edge of the STI structure 170. Divots are areas of the STI structure 170 that are substantially unfilled within a dielectric fill 192.

FIG. 7B is a detailed cross-sectional view of the conventional STI structure of FIG. 7A after an oxide layer has been applied to the region. As shown in FIG. 7B, after the oxide layer 196 has been applied, corner thinning 198 is observed at the upper edge of the STI structure 170.

FIG. 8A is a detailed cross-sectional view of a STI structure in an open region such as, for example, a periphery region of an embodiment of the invention before the application of a fifth dielectric layer, such as a gate oxide layer for instance. As shown in FIG. 8B, the upper edge 440 of the at least one STI structure 370 of the invention is substantially free of divots. FIG. 8B is a detailed cross-sectional view of a STI structure 370 after forming the fifth dielectric layer 450 according to an embodiment of the invention. As shown in FIG. 8B, after the fifth dielectric layer 450 is disposed across the semiconductor device, the outer edge 440 of the at least one STI structure 370 of the invention remains substantially free of any corner thinning. In an embodiment of the invention, the fifth dielectric layer 450 may be a gate oxide layer.

In certain embodiments of the invention, another conductive layer may be applied to the another dielectric layer. According to some embodiments of the invention, the another conductive layer may be a control gate layer.

Generally, the semiconductor of the invention may have a first shallow trench isolation (STI) structure formed in an open region such as, for example, a periphery region of the semiconductor device; a first stack structure in the open region, a portion of the first STI structure distal-proximate to and defined by the first stack structure; a trench-end offset having a distance measured from a corner of the first STI structure to an edge of the first stack in the open region; a second STI structure formed in a dense region such as, for example, an array region of the semiconductor device; and a second stack structure in the dense region, a portion of the second STI structure distal-proximate to and defined by the second stack structure. According to certain embodiments of the invention, a sidewall of the second STI structure is substantially coextensive with an edge of the second gate stack in the dense region.

In certain embodiments of the invention, the distance measured from a corner of the first STI structure to an edge of the first stack in the open region is up to about 200 Å. In other embodiments of the invention, the distance is at most about 200 Å.

In an embodiment of the invention, the second STI structure that is defined by the second stack may be substantially free of any trench-end offset. In certain embodiments of the invention, the first dielectric layer is a tunnel oxide layer.

In an embodiment of the invention, a fifth dielectric layer applied to the semiconductor device may be substantially free of any corner thinning at the corner of the first STI structure. In certain embodiments of the invention, the fifth dielectric layer is a gate oxide layer. In certain embodiments of the invention, a second conductive layer is applied to the fifth dielectric layer. For example, according to certain embodiments of the invention, the second conductive layer may be a polysilicon layer or a second polysilicon layer.

Yet, according to certain embodiments, a semiconductor device of the invention may comprise a substrate; a dense region disposed on the substrate; an open region disposed on the substrate and contiguous with the dense region at an interface region; a stack structure in the interface region having a first edge in the open region and a second edge in the dense region; a first STI structure defined in part by the first edge; a trench-end offset having a distance measured from a top corner of the first STI structure to the first edge of the stack structure in the open region; and a second STI structure defined in part by the second edge. In an embodiment of the invention, a sidewall of the second STI structure is substantially coextensive with the second edge of the stack structure.

FIG. 9A is a profile of an exemplary embodiment of a semiconductor device that has been partially processed according to a method of the invention. The semiconductor device 500 has a dense region 510 having a plurality of STI structures 530 and an open region 520 having at least one STI structure 540.

FIG. 9B is a detailed profile view of a plurality of STI structures of a semiconductor device 500 fabricated according to a method of the invention. The detailed view of FIG. 9B is taken from the marked portion 550 of the semiconductor device 500 of FIG. 9A. The outer edge 570 where one of the STI structures of the plurality of array STI structures 530 meets the first dielectric layer 280 reveals that there is substantially no trench-end offset. Without intending to be bound by the theory, the substantially reduced or substantially no trench-end offset is the result of the dimensional limitations of the dense region and the quality of the first dielectric layer 280 formed at the surface of the substrate 250.

FIG. 9C is a detailed profile view of a stack portion of at least one STI structure of an open region of a semiconductor device 500 fabricated according to a method of the invention. The detailed view of FIG. 9C is taken from the marked portion 560 of the semiconductor device 500 of FIG. 9A. Indeed, FIG. 9C shows a stack structure 575 comprising a substrate 250, a first dielectric layer 280, and a first conductive layer 300 defining a sidewall 595 of the trench 590 that may ultimately define the at least one STI structure 540 of the open region 520 situated distal-proximate to the stack structure 575. An opposing stack structure in the open region 520 (not shown in FIG. 9C) similar in configuration to the stack 575 may be disposed to fully define the at least one STI 540 of the open region 520.

The outer edge 580 where the at least one STI structure 540 meets the first dielectric layer 280 reveals that there is trench-end offset. The trench-end offset may be measured by a distance 585 from a sidewall 595 at the corner of the trench 590 to the first dielectric layer 280 or the first conductive layer 300 substantially following substrate 280. The trench 590 and the sidewall 595 define a portion of the at least one STI structure 540 of the open region 520. In certain embodiments of the invention, the distance 585 may be up to about 200 Å, about 200 Å, from about 200 Å to about 500 Å, or from about 500 Å to about 1000 Å.

Without intending to be bound by the theory, the trench-end offset resulting from the method of fabricating the semiconductor device 500 of the invention may prevent the formation of a divot upon oxide removal when the conductive layer 300 and the first dielectric layer 280 disposed in the open region 230 of the semiconductor device 210 are removed. In certain embodiments of the invention, a well implant (not shown) may be adjusted in the open region 230 of the semiconductor device 210. Following these processing steps, according to an embodiment of the invention, a fifth dielectric layer such as, for example, a gate oxide layer may be applied to a substantially flat silicon surface resulting in, without intending to be bound by theory, a substantially reduced amount of or even elimination of corner thinning upon formation of the fifth dielectric layer.

FIG. 10 provides an alternative representation at the upper corner of a STI structure of an open region in a conventional semiconductor device. FIG. 10 shows a schematic view of an upper corner of a STI structure in an open region of a conventional semiconductor device having substrate 610 showing the formation of a divot 600 in the dielectric fill layer 620 of the STI structure 630 resulting in corner thinning at an upper corner of the STI structure 630 upon formation of a gate oxide layer 640 and the control gate layer 650.

FIG. 11 provides an alternative representation at the upper corner of a STI structure in an open region of a semiconductor device of the invention. FIG. 11 shows a schematic view of an upper corner of a STI structure in an open region of a semiconductor device of the invention and fabricated according to an embodiment of the invention. The semiconductor device of FIG. 11 having a substrate 710, a dielectric fill 720 further described herein as the fourth dielectric layer, a dielectric layer 740 further described herein as the fifth dielectric layer, and a conductive layer 750. The upper corner region 700 of the STI structure 730 is substantially free of any divots and substantially free of corning rounding.

FIG. 12 is a block diagram showing certain processing modules of fabricating a semiconductor device according to certain embodiments of the invention. According to certain embodiments of the invention, the method 800 of fabricating a semiconductor device comprises a well formation module 810. The well formation module 810, according to an embodiment of the invention, may comprise the processing steps for forming a high voltage (HV) well, for example, and forming a cell well in the substrate.

The method 800 of fabricating a semiconductor device may additionally comprise a module for forming a first dielectric layer and a conductive layer such as a floating gate formation module 820, for example. The steps of the floating gate formation module 820, for example, may include formation of a first dielectric layer (for example, a tunnel oxide layer according to certain embodiments of the invention) and application of a conductive layer (for example, a polysilicon layer according to certain embodiments of the invention). The floating gate formation module 820 may additionally comprise processing steps directed to the deposition of a buffer and/or a sacrificial film layer.

A shallow trench isolation (STI) structure module 830 of the method 800 may comprise processing steps directed to patterning and etching the STI structures, the process of applying and etching back a liner layer, which may help to protect the upper corner of the STI module from forming a divot and subsequent corner thinning. The STI structure module 830 may additionally comprise a step or steps directed to filling in the trench of the STI structure with a dielectric fill layer, for example, an oxide layer according to certain embodiments of the invention. A planarization processing step and a wet etching step may be used for polishing the dielectric fill layer and one or both of a buffer and a sacrificial film layer, according to certain embodiments of the invention.

A method 800 of fabricating a semiconductor device may additionally comprise a gate oxide module 840 that can include, for example, steps directed to a process to form a low voltage region; steps directed to a process to form a H/LV dielectric layer such as a gate oxide layer; and steps directed to a process to form another conductor layer such as a control gate, for example.

The control gate, CELL, source/drain module, and back end of the layer module 850 of the method 800 of fabricating a semiconductor device may comprise steps directed to word line patterning processing, CMOS pattern processing, adjustment of the cell device, adjustment to the MOS device, interlayer dielectric (ILD) processing, and back end of the line (BEOL) layer processing.

FIG. 13 is a flowchart showing the steps of fabricating a semiconductor device according to an embodiment of the invention. The method 900 of fabricating a semiconductor device comprises a step of providing a semiconductor having a substrate, a first dielectric layer, a first conductive layer, and a second dielectric layer 910. In certain embodiments of the invention, the second dielectric layer may include more than one dielectric layer such as, for example, a dual hard mask layer. The method 900 additionally may comprise a step of patterning and etching the semiconductor device to form one or more trenches to define one or more STI structures in a dense region such as, for example, an array region and at least one STI structure in an open region such as, for example, a periphery region 920.

The method 900 may additionally comprise applying a first photoresist layer to the dense region 930, depositing a liner layer or a third dielectric layer to the semiconductor device 940, and etching the semiconductor device to achieve a desired depth of the at least one STI structure and leaving a protective portion of the liner layer at a sidewall of the at least one STI structure 950. In certain embodiments of the invention, the protective portion of the liner layer may be located at about the first dielectric layer. In certain embodiments of the invention, the protective portion of the liner layer extends from the first dielectric layer to a portion of the first conductive layer. In certain embodiments of the invention, the protective portion of the liner layer extends from the first dielectric layer to a portion of the substrate. According to certain embodiments of the invention, the liner layer may then be removed and leaving a space for a fill-in dielectric as a protective area.

The method 900 may additionally comprise removing the protective portion of the liner layer to define an open space in the sidewall 960, removing the first photoresist layer 970, applying a second photoresist layer to the open region 980, and etching the one or more STI structures of the dense region to a desired depth 990. In certain embodiments of the invention, the method 900 may include removing the second photoresist 1000 and applying a dielectric fill layer or a fourth dielectric layer to substantially fill the one or more STI structures and the at least one STI structure 1010 with a dielectric material.

According to an embodiment, a fifth dielectric layer such as, for example, a gate oxide layer applied to the semiconductor fabricated according to the aforementioned method of the invention, may be substantially free of corner thinning at an upper corner of a STI structure in the open region. Additionally, a stack in a dense region of the semiconductor fabricated according to the aforementioned method of the invention may be substantially free of any trench-end offset.

An aspect of the invention provides a semiconductor device fabricated according to the processes or methods for fabricating a semiconductor device of the invention. In certain other embodiments of the invention, a semiconductor device may be fabricated using any methods as described herein.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Moreover, although the foregoing descriptions and the associated drawings describe exemplary embodiments in the context of certain exemplary combinations of elements and/or functions, it should be appreciated that different combinations of elements and/or functions may be provided by alternative embodiments without departing from the scope of the appended claims. In this regard, for example, different combinations of elements and/or functions than those explicitly described above are also contemplated as may be set forth in some of the appended claims. Although specific terms are employed herein, they are used in a generic and descriptive sense only and not for purposes of limitation.

What is claimed is:

1. A semiconductor device comprising:
a first shallow trench isolation (STI) structure formed in an open region of the semiconductor device;
a first stack structure in the open region, a portion of the first STI structure defined by the first stack structure;
a trench-end offset having a distance measured from a top corner of the first STI structure to an edge of the first stack in the open region;
a second STI structure formed in a dense region of the semiconductor device; and
a second stack structure in the dense region, a portion of the second STI structure defined by the second stack structure,
wherein a sidewall of the second STI structure is substantially coextensive with an edge of the second gate stack in the dense region.

2. The semiconductor device of claim 1, wherein the open region is a periphery region and the dense region is an array region.

3. The semiconductor device of claim 1, wherein the distance is up to about 200 Å.

4. The semiconductor device of claim 1, wherein the second STI structure defined by the second stack structure is substantially free of any trench-end offset.

5. The semiconductor device of claim 1, wherein a dielectric layer applied to the semiconductor device is substantially free of corner thinning at the corner of the first STI structure.

6. The semiconductor device of claim 5, wherein the dielectric layer is a gate oxide layer.

7. A semiconductor device comprising:
an interface region for a first region and a second region on a substrate;
a stack structure in the interface region, the stack structure having a first edge adjacent to the first region and a second edge adjacent to the second region;
a first shallow trench isolation (STI) structure distal-proximate to the first edge of the stack structure;
a trench-end offset having a distance measured from a top corner of the first STI structure to the first edge of the stack structure in the first region; and
a second STI structure distal-proximate to the second edge of the stack structure,
wherein a sidewall of the second STI structure is substantially coextensive with the second edge of the stack structure.

8. The semiconductor device of claim 7, wherein the first region is a periphery region and the second region is an array region.

9. The semiconductor device of claim 7, wherein the trench-end offset is up to about 200 Å.

10. The semiconductor device of claim 7, wherein the first STI structure is substantially free of any trench-end offset.

11. The semiconductor device of claim 7, additionally comprising a dielectric layer that is substantially free of corner thinning at a corner of the first STI structure.

12. A method of fabricating a semiconductor device comprising:
providing a semiconductor device having a substrate, a first dielectric layer, a first conductive layer, and a second dielectric layer;
patterning and etching the semiconductor device to form one or more trenches defining one or more shallow trench isolation (STI) structures in a dense region and at least one STI structure in an open region;
applying a first photoresist layer to the dense region;
depositing a third dielectric layer on the semiconductor device; and
etching to achieve a desired depth of the at least one STI structure and leaving a protective portion of the third dielectric layer at a sidewall of the at least one STI structure in the open region.

13. The method of claim 12, wherein the protective portion of the third dielectric layer is at least about 200 Å.

14. The method of claim 12, additionally comprising:
removing the third dielectric layer to define an open space in the sidewall;
removing the first photoresist layer;
applying a second photoresist layer to the open region;
etching the one or more STI structures to another desired depth; and
removing the second photoresist layer.

15. A method of claim 14, additionally comprising applying a fourth dielectric layer to substantially fill the one or more STI structures, the at least one STI structure, and the open space.

16. The method of claim 15, additionally comprising forming a fifth dielectric layer.

17. The method of claim 16, wherein the fifth dielectric layer is substantially free of corner thinning at a corner of the at least one STI structure.

18. A semiconductor device fabricated by:
providing a semiconductor device having a substrate a first dielectric layer, a first conductive layer, and a second dielectric layer;
patterning and etching the semiconductor device to form one or more trenches defining one or more shallow trench isolation (STI) structures in a dense region and at least one STI structure in an open region;
applying a first photoresist layer to the dense region;
depositing a third dielectric layer to the semiconductor device;
etching to achieve a desired depth of the at least one STI structure and leaving a protective portion of the third dielectric layer at a sidewall of the at least on STI structure;
removing the third dielectric layer;
removing the first photoresist layer;
applying a second photoresist layer to the open region;
etching the one or more STI structures to another desired depth;
removing the second photoresist layer; and
applying a fourth dielectric layer to substantially fill the one or more STI structures and the at least one STI structure.

19. The semiconductor device of claim 18, additionally comprising forming a fifth dielectric layer.
